(19) United States
(12) Patent Application Publication
(10) Pub. No.: US 2026/0182347 A1
(43) Pub. Date: Jun. 25, 2026

(54) SEMICONDUCTOR PACKAGE

(71) Applicant: Samsung Electronics Co., Ltd., Suwon-si (KR)

(72) Inventors: Hongjin KIM, Suwon-si (KR); Kihong JEONG, Suwon-si (KR); Dongok KWAK, Suwon-si (KR)

(73) Assignee: Samsung Electronics Co., Ltd., Suwon-si (KR)

(21) Appl. No.: 19/417,804

(22) Filed: Dec. 12, 2025

(30) Foreign Application Priority Data
Dec. 20, 2024 (KR) 10-2024-0193320

(51) Int. Cl. H10W 20/43; H10W 72/50

(52) U.S. Cl. CPC H10W 20/432; H10W 72/5453

(57) ABSTRACT

A semiconductor package may include a package substrate, a first semiconductor chip on the package substrate, a second semiconductor chip laterally offset from the first semiconductor chip and arranged on the first semiconductor chip, a first substrate pad, a second substrate pad, and a first side substrate pad, a first conductive pattern, a first intersecting conductive pattern. The first intersecting conductive pattern may be spaced apart from the first conductive pattern. The first substrate pad and the second substrate pad may be laterally spaced apart from the first semiconductor chip. The first side substrate pad may be arranged in a direction of a first side surface of the first semiconductor chip. The first and second semiconductor chips may each include a first chip pad and a second chip pad, where a first length of the first chip pad may be greater than a second length of the second chip pad.

### CROSS-REFERENCE TO RELATED APPLICATION

This application is based on and claims priority under 35 U.S.C. § 119 to Korean Patent Application No. 10-2024-0193320, filed on Dec. 20, 2024, in the Korean Intellectual Property Office, the disclosure of which is incorporated by reference herein in its entirety.

### BACKGROUND

Inventive concepts relate to a semiconductor package, and more particularly, to a semiconductor package including stacked semiconductor chips and wiring on the semiconductor chips.

With rapid advancements in the electronics industry and increasing user demands, electronic devices are becoming increasingly compact and lightweight, and accordingly, higher integration and larger capacity may be required for semiconductor devices, which are key components of the electronic devices. However, there is a limitation to achieving further integration of semiconductor devices. As a result, semiconductor packages each including a plurality of semiconductor chips have been developed to achieve higher capacity. With the growing demand for higher-capacity semiconductor devices, semiconductor packages in which semiconductor chips are stacked have been developed.

A semiconductor package may include a plurality of semiconductor chips stacked on each other and electrical inputs/outputs may be made between the semiconductor chips and a package substrate through wire bonding. Because of the wire bonding of the stacked semiconductor chips, the thickness of the semiconductor package may increase, and the manufacturing process may become more complex. To overcome the aforementioned issues, a method is being considered in which stacked semiconductor chips are connected to a package substrate through patterned wiring instead of through wire bonding.

### SUMMARY

Inventive concept relate to enhancing the quality of power supplied to a semiconductor package including a plurality of stacked semiconductor chips.

Aspects of inventive concepts are not limited to the above description, and other technical aspects may be clearly understood by one of ordinary skill in the art from the descriptions provided hereinafter.

According to an embodiment of inventive concepts, a semiconductor package may include a package substrate; a first semiconductor chip on the package substrate; a second semiconductor chip on the first semiconductor chip and laterally offset from the first semiconductor chip; a plurality of chip pads, the plurality of chip pads including a first chip pad on the first semiconductor chip, a second chip pad on the first semiconductor chip, a first chip pad on the second semiconductor chip, and a second chip pad on the second semiconductor chip, respectively; a first substrate pad on the package substrate; a second substrate pad on the package substrate; a first side substrate pad on the package substrate; a first conductive pattern that extends on the first chip pad on the first semiconductor chip, the first chip pad on the second semiconductor chip, and the first substrate pad on the package substrate; and a first intersecting conductive pattern on the first chip pad of the first semiconductor chip, the first intersecting conductive pattern extending on the first semiconductor chip in a first direction. The first intersecting conductive pattern may be spaced apart from the first conductive pattern. The first substrate pad and the second substrate pad may be laterally spaced apart from the first semiconductor chip. The first side substrate pad may be apart from a first side surface of the first semiconductor chip. A first length of the first chip pad on the first semiconductor chip may be greater than a second length of the second chip pad on the first semiconductor chip.

According to an embodiment of inventive concepts, a semiconductor package may include a package substrate comprising a first substrate pad, a second substrate pad, and a first side substrate pad on an upper surface of the package substrate; a first semiconductor chip on the package substrate; a second semiconductor chip on the first semiconductor chip and laterally offset from the first semiconductor chip; a plurality of chip pads, the plurality of chip pads including a first chip pad on the first semiconductor chip, a second chip pad on the first semiconductor chip, a first chip pad on the second semiconductor chip, and a second chip pad on the second semiconductor chip, respectively; a first insulating layer extending on a side surface of the first semiconductor chip and the upper surface of the package substrate; a second insulating layer extending on a side surface of the second semiconductor chip and an upper surface of the first semiconductor chip; a first conductive pattern electrically connecting the first chip pad of the first semiconductor chip, the first chip pad of the second semiconductor chip, and the first substrate pad; a second conductive pattern electrically connecting the second chip pad of the first semiconductor chip, the second chip pad of the second semiconductor chip, and the second substrate pad; and a first intersecting conductive pattern connected to at least a portion of the first chip pad of the first semiconductor chip. The first intersecting conductive pattern may extend on the first semiconductor chip in a first direction. The second semiconductor chip may be offset from the first semiconductor chip in a second direction. The second direction may be orthogonal to the first direction. The first conductive pattern and the second conductive pattern each may extend in the second direction.

According to an embodiment of inventive concepts, a semiconductor package may include a package substrate comprising a first substrate pad, a second substrate pad, and a first side substrate pad on an upper surface of the package substrate; a first semiconductor chip on the package substrate; a second semiconductor chip on the first semiconductor chip and laterally offset from the first semiconductor chip; a plurality of chip pads, the plurality of chip pads including a first chip pad on the first semiconductor chip, a second chip pad on the first semiconductor chip, a first chip pad on the second semiconductor chip, and a second chip pad on the second semiconductor chip, respectively; a first insulating layer extending on a side surface of the first semiconductor chip and an upper surface of the package substrate; a second insulating layer extending on a side surface of the second semiconductor chip and an upper surface of the first semiconductor chip; a first conductive pattern electrically connecting the first chip pad of the first semiconductor chip, the first chip pad of the second semiconductor chip, and the first substrate pad; a second conductive pattern electrically connecting the second chip pad of the first semiconductor chip, the second chip pad of the second semiconductor chip, and the second substrate pad; and a first intersecting conductive pattern connected to at least a portion of the first chip pad of the first semiconductor chip. The second semiconductor chip may be offset from the first semiconductor chip in a second direction. The second direction may be orthogonal to the first direction. The first conductive pattern and the second conductive pattern may extend in the second direction. The first intersecting conductive pattern may be spaced apart from the second conductive pattern. The first side substrate pad may be apart of a first side surface of the first semiconductor chip. The first substrate pad and the second substrate pad may be spaced apart from the first semiconductor chip in the second direction. A first length of the first chip pad on the first semiconductor chip may be greater than a second length of the second chip pad on the first semiconductor chip. The first length may be in a range of 1.5 times to 4 times the second length. The first intersecting conductive pattern may extend on an upper surface of the first semiconductor chip, the first side surface of the first semiconductor chip, and an upper surface of the package substrate. The first intersecting conductive pattern may be electrically connected to the first side substrate pad and the first chip pad of the first semiconductor chip. The first side surface of the first semiconductor chip and the side surface of the second semiconductor chip may be arranged in a vertical direction. The first insulating layer may be spaced apart from the first substrate pad and the second substrate pad. The second insulating layer may be between the first conductive pattern and the first intersecting conductive pattern, may cover a portion of the first chip pad on the first semiconductor chip, and may cover at least a portion of the first intersecting conductive pattern on the first semiconductor chip. The first conductive pattern and the second conductive pattern may extend on the second insulating layer. A part of the first intersecting conductive pattern may extend on the side surface of the first semiconductor chip in a third direction. The third direction may be orthogonal to both the first direction and the second direction. The first conductive pattern, the first substrate pad, the first chip pad of the first semiconductor chip, the first chip pad of the second semiconductor chip, and the first side substrate pad may be configured to transmit power signals. The second conductive pattern, the second substrate pad, the second chip pad of the first semiconductor chip, and the second chip pad of the second semiconductor chip may be configured to transmit data signals.

According to an example embodiment, a method of manufacturing a semiconductor package may include attaching a plurality of semiconductor chips on a first region of a package substrate, forming a plurality of intersecting conductive patterns over the package substrate, forming a plurality of insulating layers over the plurality of intersecting conductive patterns, and forming a plurality of conductive patterns over the plurality of insulating layers and the plurality of semiconductor chips. The plurality of semiconductor chips may stacked on top of each other and laterally offset from each other. The package substrate may include a second region surrounding the first region of the package substrate. The second region of the package substrate may include a plurality of substrate pads spaced apart from each other in a first direction and a plurality of side substrate pads spaced apart from each other in a second direction. The plurality of semiconductor chips each may include a plurality of chip pads. The plurality of semiconductor chips may include a first semiconductor chip on the first region of the package substrate and a second semiconductor chip on the first semiconductor chip. The plurality of chip pads may include a first chip pad on the first semiconductor chip, a second chip pad on the first semiconductor chip, a first chip pad on the second semiconductor chip, and a second chip pad on the second semiconductor chip, respectively. The plurality of substrate pads may include a first substrate pad on the package substrate and a second substrate pad on the package substrate. The plurality of side substrate pads may include a first side substrate pad on the package substrate. The plurality of conductive patterns may include a first conductive pattern that extends on the first chip pad on the first semiconductor chip, the first chip pad on the second semiconductor chip, and the first substrate pad on the package substrate. The plurality of intersecting conductive patterns may include a first intersecting conductive pattern on the first chip pad of the first semiconductor chip. The first intersecting conductive pattern may extend on the first semiconductor chip in the first direction. The first intersecting conductive pattern may be spaced apart from the first conductive pattern. The first substrate pad and the second substrate pad may be laterally spaced apart from the first semiconductor chip. The first side substrate pad may be apart from a first side surface of the first semiconductor chip. A first length of the first chip pad on the first semiconductor chip may be greater than a second length of the second chip pad on the first semiconductor chip.

In some embodiments, the plurality of conductive patterns may include a second conductive pattern extending on the second chip pad of the first semiconductor chip, the second chip pad of the second semiconductor chip, and the second substrate pad of the package substrate. The first intersecting conductive pattern may be spaced apart from the second conductive pattern.

In some embodiments, the second direction may be orthogonal to the first direction. The first side substrate pad may be spaced apart from the first semiconductor chip in the first direction.

The first intersecting conductive pattern may extend on an upper surface of the first semiconductor chip, the first side surface of the first semiconductor chip, and an upper surface of the package substrate. The first intersecting conductive pattern may be electrically connected to the first side substrate pad and the first chip pad on the first semiconductor chip.

In some embodiments, the forming the plurality of insulating layers over the plurality of intersecting conductive patterns may include forming a second insulating layer extending on a side surface of the second semiconductor chip and an upper surface of the first semiconductor chip. The second insulating layer may be between the first conductive pattern and the first intersecting conductive pattern.

### BRIEF DESCRIPTION OF THE DRAWINGS

Embodiments will be more clearly understood from the following detailed description taken in conjunction with the accompanying drawings in which:

FIG. 1 is a perspective view of a semiconductor package according to embodiments;

FIG. 2 is a plan view of a semiconductor package according to embodiments;

FIG. 3 is a side view of a semiconductor package according to embodiments;

FIG. 4 is a plan view of a semiconductor package according to embodiments;

FIG. 5 is a plan view of a semiconductor package according to embodiments;

FIG. 6 is a plan view of a semiconductor package according to embodiments;

FIGS. 7A to 7E are plan views for explaining a method of manufacturing a semiconductor package in sequence, according to embodiments; and

FIG. 8 is a perspective view of a semiconductor package according to embodiments.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

The notion that elements are “substantially the same” may indicate that the element may be completely the same and may also indicate that the elements may be determined to be the same in consideration of errors or deviations occurring during a process.

Hereinafter, one or more embodiments of inventive concepts will be described in detail with reference to the attached drawings.

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions may be exaggerated for clarity. Like reference characters and/or numerals in the drawings denote like elements, and thus their description may not be repeated.

In the present specification, the first direction may refer to the X direction, the second direction may refer to the Y direction, and the first direction may be perpendicular to the second direction. The third direction may refer to the Z direction and may be perpendicular to each of the first direction and the second direction. The horizontal plane or plane may refer to the X-Y plane. The upper surface of a specific object refers to a surface located in a positive third direction with respect to the specific object, and the lower surface of the specific object refers to a surface located in a negative third direction with respect to the specific object.

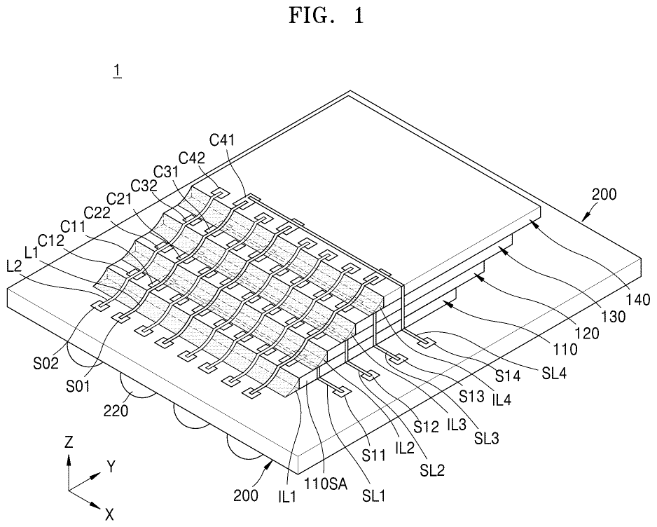

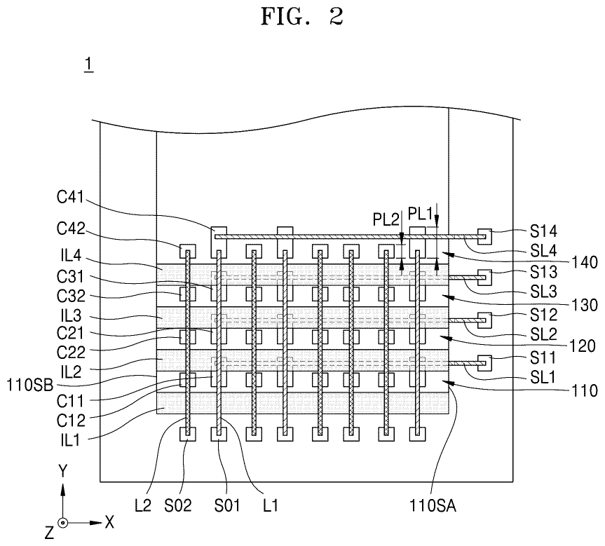

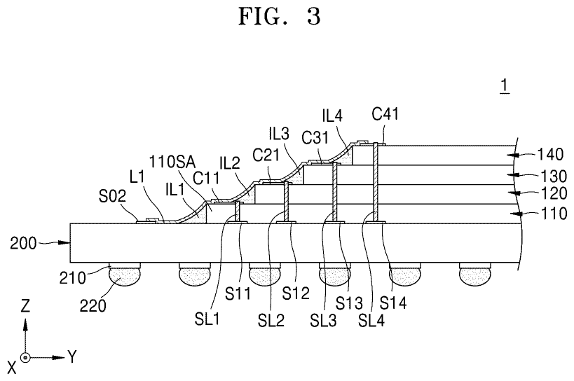

FIG. 1 is a perspective view of a semiconductor package 1 according to embodiments. FIG. 2 is a plan view of the semiconductor package 1 according to embodiments. FIG. 3 is a side view of the semiconductor package 1 according to embodiments.

Referring to FIGS. 1 to 3, the semiconductor package 1 may include a package substrate 200, a first semiconductor chip 110, a second semiconductor chip 120, a third semiconductor chip 130, and a fourth semiconductor chip 140.

The first semiconductor chip 110 may be provided on the upper surface of the package substrate 200. The second semiconductor chip 120 may be arranged on the first semiconductor chip 110. Similarly, the third semiconductor chip 130 may be arranged on the second semiconductor chip 120, and the fourth semiconductor chip 140 may be arranged on the third semiconductor chip 130.

The first semiconductor chip 110 to the fourth semiconductor chip 140 may be offset in a lateral direction and stacked sequentially. The second semiconductor chip 120 may be offset from the first semiconductor chip 110 in a lateral direction and provided on the first semiconductor chip 110. For example, the second semiconductor chip 120 may be offset from the first semiconductor chip 110 in the positive second direction (the +Y direction). Similarly, the third semiconductor chip 130 may be arranged on the second semiconductor chip 120 and offset therefrom in the lateral direction. The fourth semiconductor chip 140 may be arranged on the third semiconductor chip 130 and offset therefrom in the lateral direction.

The first semiconductor chip 110 to the fourth semiconductor chip 140 may be referred to as a semiconductor chip stack. The semiconductor chip stack may include a plurality of semiconductor chips that are stacked in a stepped arrangement.

On the upper surface of the package substrate 200, a first substrate pad S01, a second substrate pad S02, a first side substrate pad S11, a second side substrate pad S12, a third side substrate pad S13, and a fourth side substrate pad S14 may be provided. The first substrate pad S01, the second substrate pad S02, the first side substrate pad S11, the second side substrate pad S12, the third side substrate pad S13, and the fourth side substrate pad S14 may be referred to collectively as package substrate pads.

The first substrate pad S01 and the second substrate pad S02 on the upper surface of the package substrate 200 may be spaced apart from the first semiconductor chip 110 in the negative second direction (the −Y direction) and provided on the package substrate 200. The first side substrate pad S11, the second side substrate pad S12, the third side substrate pad S13, and the fourth side substrate pad S14 may be spaced apart from the first semiconductor chip 110 in the positive first direction (the +X direction) and provided on the package substrate 200. In the present specification, the description that the components are spaced apart from each other in the first direction may indicate that the components are spaced apart from each other in the positive first direction or the negative first direction, and the description that the components are spaced apart from each other in the second direction may indicate that the components are spaced apart from each other in the positive second direction or the negative second direction.

On the lower surface of the package substrate 200, external connection pads 210 shown in FIG. 3 and external connection terminals 220 included in the external connection pads 210 may be arranged. Through the external connection terminals 220, an external electronic device, for example, a Printed Circuit Board (PCB), may be connected to the package substrate 200. The package substrate 200 may be, for example, a PCB or a redistribution structure.

When the package substrate 200 is a PCB, the package substrate 200 may include a base layer, and the base layer may include a plurality of stacked sub-base layers. A solder resist layer may cover the upper surface and the lower surface of the base layer. The first substrate pad S01, the second substrate pad S02, the first side substrate pad S11, the second side substrate pad S12, the third side substrate pad S13, the fourth side substrate pad S14, and the external connection pads 221 may not be covered by the solder resist layer and may be exposed to the upper surface and the lower surface of the package substrate 200, respectively.

In some embodiments, the base layer may include at least one material selected from among phenol resin, epoxy resin, and polyimide. For example, the base layer may include at least one material selected from among Flame Retardant 4 (FR4), tetrafunctional epoxy, polyphenylene ether, epoxy/polyphenylene oxide, Bismaleimide Triazine (BT), Thermount, cyanate ester, polyimide, and liquid crystal polymer.

When the package substrate 200 is a redistribution structure, the package substrate 200 may include a plurality of redistribution insulating layers and a plurality of redistribution patterns included in the redistribution insulating layers. The redistribution pattern may include a plurality of redistribution line patterns and a plurality of redistribution via patterns. The redistribution line patterns may be arranged between redistribution insulating layers, and the redistribution via patterns may penetrate the redistribution insulating layers and connect between the redistribution line patterns.

In some embodiments, the redistribution insulating layer may include an insulating material, for example, Photo Imageable Dielectric (PID) resin. In this case, the redistribution insulating layer may further include an inorganic filler. The redistribution pattern may include a conductive material, for example, copper (Cu), aluminum (Al), silver (Ag), tin (Sn), gold (Au), nickel (Ni), lead (Pb), titanium (Ti), or an alloy thereof.

A first chip pad C11 and a second chip pad C12 of the first semiconductor chip 110 may be provided on the upper surface of the first semiconductor chip 110. The first chip pad C11 and the second chip pad C12 of the first semiconductor chip 110 may be referred to collectively as first semiconductor chip pads. For example, as shown in FIG. 1, the first semiconductor chip pads of the first semiconductor chip 110 may be arranged on the first semiconductor chip 110 in a direction and arranged in sequence.

The first chip pad C11 and the second chip pad C12 may be provided on the upper surface of the first semiconductor chip 110 that is exposed because of the offset of the second semiconductor chip 120. That is, the first semiconductor chip pads may be located on the exposed upper surfaces of the first semiconductor chips 110 in the semiconductor chip stack in a stepped form. The first chip pad C11 and the second chip pad C12 may be exposed through a passivation layer arranged on the upper surface of the first semiconductor chip 110. The first chip pad C11 and the second chip pad C12 exposed from the passivation layer may be connected to a first conductive pattern L1 and a second conductive pattern L2, respectively. This configuration may be similarly applied to second semiconductor chip pads of the second semiconductor chip 120, third semiconductor chip pads of the third semiconductor chip 130, and fourth semiconductor chip pads of the fourth semiconductor chip 140.

A first chip pad C21 and a second chip pad C22 of the second semiconductor chip 120 may be provided on the upper surface of the second semiconductor chip 120. The first chip pad C21 and the second chip pad C22 of the second semiconductor chip 120 may be referred to collectively as second semiconductor chip pads. A first chip pad C31 and a second chip pad C32 of the third semiconductor chip 130 may be provided on the upper surface of the third semiconductor chip 130. The first chip pad C31 and the second chip pad C32 of the third semiconductor chip 130 may be referred to collectively as the third semiconductor chip pads. A first chip pad C41 and a second chip pad C42 of the fourth semiconductor chip 140 may be provided on the upper surface of the fourth semiconductor chip 140. The first chip pad C41 and the second chip pad C42 of the fourth semiconductor chip 140 may be referred to collectively as the fourth semiconductor chip pads.

The first chip pad C41 of the fourth semiconductor chip 140 may have a length greater than that of the second chip pad C42 in one direction. For example, as shown in FIG. 2, a first pad length PL1, which is the length of the first chip pad C41 in the first direction, may be greater than a second pad length PL2, which is the length of the second chip pad C42 in the first direction. For example, the first pad length PL1 may be in a range from about 1.5 times to about 4 times the second pad length PL2. The first chip pad C31 and the second chip pad C32 of the third semiconductor chip 130 may have the same size relationship as the first chip pad C41 and the second chip pad C42 of the fourth semiconductor chip 140.

The length of the first chip pad C31 of the third semiconductor chip 130 in one direction may be greater than the length of the second chip pad C32 in one direction, and the length of the first chip pad C31 of the third semiconductor chip 130 in one direction may be in a range from about 1.5 times to about 4 times the length of the second chip pad C32 in one direction. Similarly, the size relationship between the first chip pad C11 and the second chip pad C12 of the first semiconductor chip 110 and the size relationship between the first chip pad C21 and the second chip pad C22 of the second semiconductor chip 120 may be the same as the size relationship between the first chip pad C41 and the second chip pad C42 of the fourth semiconductor chip 140.

The arrangement order of the first semiconductor chip pads on the first semiconductor chip 110 in one direction may be the same as the arrangement order of chip pads on another semiconductor chip in one direction. For example, the arrangement order of the first chip pad C11 and the second chip pad C12 included in the first semiconductor chip pads of the first semiconductor chip 110 in the positive first direction (the +X direction) may be the same as that of the first chip pad C21 and the second chip pad C22 included in the second semiconductor chip pads of the second semiconductor chip 120 in the positive first direction (the +X direction).

For example, the arrangement order of the first chip pad C11 and the second chip pad C12 on the first semiconductor chip 110 in the positive first direction (the +X direction) may be the second chip pad C12, the first chip pad C11, the second chip pad C12, the first chip pad C11, the second chip pad C12, the second chip pad C12, the second chip pad C12, and the first chip pad C11. Similarly, the arrangement order of the first chip pad C21 and the second chip pad C22 on the second semiconductor chip 120 in the positive first direction (the +X direction) may be the second chip pad C22, the first chip pad C21, the second chip pad C22, the first chip pad C21, the second chip pad C22, the second chip pad C22, the second chip pad C22, and the first chip pad C21. The arrangement order of the first chip pad C31 and the second chip pad C32 on the third semiconductor chip 130 in the positive first direction (the +X direction) as well as the arrangement order of the first chip pad C41 and the second chip pad C42 on the fourth semiconductor chip 140 in the positive first direction (the +X direction) may be substantially the same as the order described above.

The first semiconductor chip 110 may include a first semiconductor substrate. The first semiconductor substrate may include, for example, silicon (Si). Alternatively, the first semiconductor substrate may include a semiconductor element such as germanium (Ge) or a compound semiconductor such as silicon carbide (SiC), gallium arsenide (GaAs), indium arsenide (InAs), or indium phosphide (InP). Alternatively, the third semiconductor substrate 131 may have a Silicon-on-Insulator (SOI) structure. For example, the first semiconductor substrate may include a buried oxide (BOX) layer. The first semiconductor substrate may include conductive regions, for example, wells doped with impurities. The first semiconductor substrate may have various device isolation structures, such as a Shallow Trench Isolation (STI) structure. The first semiconductor substrate may have a first active surface adjacent to the upper surface of the first semiconductor chip 110 and a surface opposite to the active surface, that is, a first inactive surface corresponding to the lower surface of the first semiconductor chip 110. The first inactive surface may be referred to as a first substrate rear surface.

A semiconductor device including various types of individual devices may be formed on the active surface of the first semiconductor substrate. The individual devices may include various microelectronic devices, for example, a metal-oxide-semiconductor field effect transistor (MOSFET) such as a complementary metal-insulator-semiconductor (CMOS) transistor, a floating cate transistor, system large scale integration (LSI), a micro-electro-mechanical system (MEMS), an active element, a passive element, or the like.

The individual devices may be electrically connected to the conductive regions of the first semiconductor substrate. Also, the individual devices may be electrically separated from other neighboring individual devices by insulating layers, respectively.

For example, the first semiconductor chip 110 may be a memory semiconductor chip. In some embodiments, the memory semiconductor device may be a non-volatile memory semiconductor device, such as flash memory, Phase-Change Random Access Memory (PRAM), Magneto-Resistive Random Access Memory (MRAM), Ferroelectric Random Access Memory (FeRAM), or Resistive Random Access Memory (RRAM). The flash memory may be, for example, V-NAND flash memory. In some embodiments, the memory semiconductor device may be a volatile memory semiconductor chip, such as Dynamic Random Access Memory (DRAM) or Static Random Access Memory (SRAM).

The descriptions regarding the first semiconductor substrate included in the first semiconductor chip 110, the first active surface, and the first inactive surface may be applied to the second semiconductor chip 120, the third semiconductor chip 130, and the fourth semiconductor chip 140.

A first adhesive film may be provided on the lower surface of the first semiconductor chip 110 and attached to a structure thereunder. For example, the first adhesive film may be provided on the lower surface of the first semiconductor chip 110, and the first semiconductor chip 110 may be attached to the package substrate 200 by the first adhesive film. The first adhesive film may include a Non-Conductive Film (NCF) or a Non-Conductive Paste (NCP). A second adhesive film, a third adhesive film, and a fourth adhesive film may be provided on lower surfaces of the second semiconductor chip 120, the third semiconductor chip 130, and the fourth semiconductor chip 140, respectively. The second adhesive film may provide adhesion between the first semiconductor chip 110 and the second semiconductor chip 120, the third adhesive film may provide adhesion between the second semiconductor chip 120 and the third semiconductor chip 130, and the fourth adhesive film may provide adhesion between the third semiconductor chip 130 and the fourth semiconductor chip 140.

A first insulating layer IL1 may be provided, the first insulating layer IL1 extending on the side surface of the first semiconductor chip 110 and the upper surface of the package substrate 200. The first insulating layer IL1 may extend on a portion of the upper surface of the package substrate 200, which is located between the first semiconductor chip 110 and the first substrate pad S01 and the second substrate pad S02, and on the side surface of the first semiconductor chip 110, which faces the first substrate pad S01 and the second substrate pad S02. The first insulating layer IL1 may be provided to fill the stepped structure formed between the upper surface of the package substrate 200 and the side surface of the first semiconductor chip 110. The first insulating layer IL1 may be spaced apart from the first substrate pad S01 and the second substrate pad S02.

A second insulating layer IL2 may extend on the side surface of the second semiconductor chip 120 and the upper surface of the first semiconductor chip 110. The second insulating layer IL2 may cover a portion of the first chip pad C21. The second insulating layer IL2 may cover a portion of the second chip pad C22 or may be spaced apart from the second chip pad C22. The second insulating layer IL2 may extend on the side surface of the second semiconductor chip 120, which is oriented in a direction similar to the direction of the side surface of the first semiconductor chip 110 that faces the first substrate pad S01 and the second substrate pad S02, and on the upper surface of the first semiconductor chip 110, which is adjacent to the side surface of the second semiconductor chip 120.

The third insulating layer IL3 may extend on the side surface of the third semiconductor chip 130 and the upper surface of the second semiconductor chip 120. The third insulating layer IL3 may cover a portion of the first chip pad C31. The third insulating layer IL3 may cover a portion of the second chip pad C32 or may be spaced apart from the second chip pad C32. The third insulating layer IL3 may extend on the side surface of the third semiconductor chip 130, which is oriented in a direction similar to the direction of the side surface of the first semiconductor chip 110 that faces the first substrate pad S01 and the second substrate pad S02, and on the upper surface of the second semiconductor chip 120, which is adjacent to the side surface of the third semiconductor chip 130.

The fourth insulating layer IL4 may extend on the side surface of the fourth semiconductor chip 140 and the upper surface of the third semiconductor chip 130. The fourth insulating layer IL4 may cover a portion of the first chip pad C41. The fourth insulating layer IL4 may cover a portion of the second chip pad C42 or may be spaced apart from the second chip pad C42. The fourth insulating layer IL4 may extend on the side surface of the fourth semiconductor chip 140, which is oriented in a direction similar to the direction of the side surface of the first semiconductor chip 110 that faces the first substrate pad S01 and the second substrate pad S02, and on the upper surface of the third semiconductor chip 130, which is adjacent to the side surface of the fourth semiconductor chip 140.

The first conductive pattern L1 and the second conductive pattern L2 may each extend along the upper surface of the first insulating layer IL1, the upper surface of the first semiconductor chip 110, the upper surface of the second insulating layer IL2, the upper surface of the second semiconductor chip 120, the upper surface of the third insulating layer IL3, the upper surface of the third semiconductor chip 130, the upper surface of the fourth insulating layer IL4, and the upper surface of the fourth semiconductor chip 140. A portion of the first conductive pattern L1 and a portion of the second conductive pattern L2 may each extend from the upper surface of the first insulating layer IL1 to the upper surface of the package substrate 200.

The first conductive pattern L1 may be electrically connected to the first chip pad C11 of the first semiconductor chip 110, the first chip pad C21 of the corresponding second semiconductor chip 120, the first chip pad C31 of the corresponding third semiconductor chip 130, and the first chip pad C41 of the corresponding fourth semiconductor chip 140. In addition, the first conductive pattern L1 may be electrically connected to the first substrate pad S01 of the package substrate 200.

The second conductive pattern L2 may be electrically connected to the second chip pad C12 of the first semiconductor chip 110, the second chip pad C22 of the corresponding second semiconductor chip 120, the second chip pad C32 of the corresponding third semiconductor chip 130, and the second chip pad C42 of the corresponding fourth semiconductor chip 140. Also, the second conductive pattern L2 may be electrically connected to the second substrate pad S02 of the package substrate 200.

A first intersecting conductive pattern SL1 may be connected to the first chip pad C11 of the first semiconductor chip 110 but not be connected to the second chip pad C12. The first intersecting conductive pattern SL1 may be connected to a portion of the first chip pad C11 having a length that is relatively greater than that of the second chip pad C12. The first intersecting conductive pattern SL1 may extend on the upper surface of the first semiconductor chip 110, a first side surface 110SA of the first semiconductor chip 110, and the upper surface of the package substrate 200. The first intersecting conductive pattern SL1 may be connected to the first chip pad C11 of the first semiconductor chip 110 and the first side substrate pad S11. A second side surface 110SB may be opposite to the first side surface 110SA of the first semiconductor chip 110.

The first side substrate pad S11 may be provided on the package substrate 200 in a direction similar to the direction in which the first chip pad C11 and the second chip pad C12 of the first semiconductor chip 110 are arranged. Therefore, in a plan view, the first side substrate pad S11 may be electrically connected to the first intersecting conductive pattern SL1 without a significant change in the direction of the first intersecting conductive pattern SL1.

In some embodiments, the first intersecting conductive pattern SL1 may extend in a direction perpendicular to the direction in which the first semiconductor chip 110 to the fourth semiconductor chip 140 are offset. As shown in FIG. 1, for example, the first semiconductor chip 110 to the fourth semiconductor chip 140 are offset and stacked in sequence in the positive second direction, and the first intersecting conductive pattern SL1 may extend in the first direction (the X direction) that is orthogonal to the second direction.

In some embodiments, the first intersecting conductive pattern SL1 may extend in a direction that is the same as the direction in which the first chip pad C11 and the second chip pad C12 on the first semiconductor chip 110 are arranged. For example, the first chip pad C11 and the second chip pad C12 are arranged in a direction parallel to the first direction, and the first intersecting conductive pattern SL1 may extend in the direction parallel to the first direction.

The extension direction of the first intersecting conductive pattern SL1 may be similarly applied to the extension directions of a second intersecting conductive pattern SL2, a third intersecting conductive pattern SL3, and a fourth intersecting conductive pattern SL4.

The first intersecting conductive pattern SL1 may extend on the upper surface of the first semiconductor chip 110 and be bent in a vertical direction, thus extending to the first side surface 110SA of the first semiconductor chip 110. The first intersecting conductive pattern SL1 may be bent on the first side surface 110SA of the first semiconductor chip 110 in the vertical direction and extend to the upper surface of the package substrate 200.

The second intersecting conductive pattern SL2 may be connected to the first chip pad C21 of the second semiconductor chip 120 but not be connected to the second chip pad C22. The second intersecting conductive pattern SL2 may be connected to a portion of the first chip pad C21 having a length that is relatively greater than that of the second chip pad C22.

The second intersecting conductive pattern SL2 may extend on the upper surface of the second semiconductor chip 120, the side surface of the second semiconductor chip 120, the first side surface 110SA of the first semiconductor chip 110, and the upper surface of the package substrate 200. The second intersecting conductive pattern SL2 may be connected to the first chip pad C21 of the second semiconductor chip 120 and the second side substrate pad S12.

The second side substrate pad S12 may be provided on the package substrate 200 in a direction similar to the direction in which the first chip pad C21 and the second chip pad C22 of the second semiconductor chip 120 are arranged. Therefore, in a plan view, the second side substrate pad S12 may be electrically connected to the second intersecting conductive pattern SL2 without a significant change in the direction of the second intersecting conductive pattern SL2.

In some embodiments, the second intersecting conductive pattern SL2 may extend in the direction that is perpendicular to the direction in which the first semiconductor chip 110 to the fourth semiconductor chip 140 are offset. Alternatively, the second intersecting conductive pattern SL2 may extend in the direction that is the same as the direction in which the first chip pad C21 and the second chip pad C22 on the second semiconductor chip 120 are arranged.

The second intersecting conductive pattern SL2 may extend to the side surface of the second semiconductor chip 120 and the first side surface 110SA of the first semiconductor chip 110. The second intersecting conductive pattern SL2 may extend on the upper surface of the second semiconductor chip 120 and may be bent in the vertical direction, thus extending to the side surface of the second semiconductor chip 120 and the first side surface 110SA of the first semiconductor chip 110. The second intersecting conductive pattern SL2 may be bent on the first side surface 110SA of the first semiconductor chip 110 in the vertical direction and extend to the upper surface of the package substrate 200.

The third intersecting conductive pattern SL3 may be connected to the first chip pad C31 of the third semiconductor chip 130 but not be connected to the second chip pad C32. The third intersecting conductive pattern SL3 may be connected to a portion of the first chip pad C31 having a length that is relatively greater than that of the second chip pad C32.

The third intersecting conductive pattern SL3 may extend on the upper surface of the third semiconductor chip 130, the side surface of the third semiconductor chip 130, the side surface of the second semiconductor chip 120, the first side surface 110SA of the first semiconductor chip 110, and the upper surface of the package substrate 200. The third intersecting conductive pattern SL3 may be connected to the first chip pad C31 of the third semiconductor chip 130 and the third side substrate pad S13.

The third side substrate pad S13 may be provided on the package substrate 200 in a direction similar to the direction in which the first chip pad C31 and the second chip pad C32 of the third semiconductor chip 130 are arranged. Therefore, in a plan view, the third side substrate pad S13 may be electrically connected to the third intersecting conductive pattern SL3 without a significant change in the direction of the third intersecting conductive pattern SL3.

In some embodiments, the third intersecting conductive pattern SL3 may extend in the direction that is perpendicular to the direction in which the first semiconductor chip 110 to the fourth semiconductor chip 140 are offset, and alternatively, the third intersecting conductive pattern SL3 may extend in the direction that is the same as the direction in which the first chip pad C31 and the second chip pad C32 on the third semiconductor chip 130 are arranged.

The third intersecting conductive pattern SL3 may extend on the upper surface of the third semiconductor chip 130 and may be bent in the vertical direction, thus extending to the side surface of the third semiconductor chip 130, the side surface of the second semiconductor chip 120, and the first side surface 110SA of the first semiconductor chip 110. The third intersecting conductive pattern SL3 may be bent on the first side surface 110SA of the first semiconductor chip 110 in the vertical direction and extend to the upper surface of the package substrate 200.

The fourth intersecting conductive pattern SL4 may be connected to the first chip pad C41 of the fourth semiconductor chip 140 but not be connected to the second chip pad C42. The fourth intersecting conductive pattern SL4 may be connected to a portion of the first chip pad C41 having a length that is relatively greater than that of the second chip pad C42.

The fourth intersecting conductive pattern SL4 may extend on the upper surface of the fourth semiconductor chip 140, the side surface of the fourth semiconductor chip 140, the side surface of the third semiconductor chip 130, the side surface of the second semiconductor chip 120, the first side surface 110SA of the first semiconductor chip 110, and the upper surface of the package substrate 200. The fourth intersecting conductive pattern SL4 may be connected to the first chip pad C41 of the fourth semiconductor chip 140 and the fourth side substrate pad S14.

The fourth side substrate pad S14 may be provided on the package substrate 200 in a direction similar to the direction in which the first chip pad C41 and the second chip pad C42 of the fourth semiconductor chip 140 are arranged. Therefore, in a plan view, the fourth side substrate pad S14 may be electrically connected to the fourth intersecting conductive pattern SL4 without a significant change in the direction of the fourth intersecting conductive pattern SL4.

In some embodiments, the fourth intersecting conductive pattern SL4 may extend in the direction that is perpendicular to the direction in which the first semiconductor chip 110 to the fourth semiconductor chip 140 are offset, and alternatively, the fourth intersecting conductive pattern SL4 may extend in the direction that is the same as the direction in which the first chip pad C41 and the second chip pad C42 on the fourth semiconductor chip 140 are arranged.

The fourth intersecting conductive pattern SL4 may extend on the upper surface of the fourth semiconductor chip 140 and may be bent in the vertical direction, thus extending to the side surface of the fourth semiconductor chip 140, the side surface of the third semiconductor chip 130, the side surface of the second semiconductor chip 120, and the first side surface 110SA of the first semiconductor chip 110. The fourth intersecting conductive pattern SL4 may be bent on the first side surface 110SA of the first semiconductor chip 110 in the vertical direction and extend to the upper surface of the package substrate 200.

The second insulating layer IL2 may cover at least a portion of the first intersecting conductive pattern SL1 extending on the upper surface of the first semiconductor chip 110. In some embodiments, the second insulating layer IL2 may entirely cover the first intersecting conductive pattern SL1 extending on the upper surface of the first semiconductor chip 110.

The second insulating layer IL2 may be arranged between the first conductive pattern L1, the second conductive pattern L2, and the first intersecting conductive pattern SL1; thus, the first conductive pattern L1 may be spaced apart from the first intersecting conductive pattern SL1 by the second insulating layer IL2, and the second conductive pattern L2 may be spaced apart from the first intersecting conductive pattern SL1 by the second insulating layer IL2. The first intersecting conductive pattern SL1 may be connected to the first chip pad C11 at a portion of the first chip pad C11 having a length that is greater than that of the second chip pad C12. The first insulating layer IL1 may cover the first intersecting conductive pattern SL1, and thus, the first chip pad C11 may be connected to the first conductive pattern L1 on the remaining portions except for the portion of the first chip pad C11. Because the first conductive pattern L1 and the first intersecting conductive pattern SL1 are connected to the first chip pad C11, the first chip pad C11, the first conductive pattern L1, and the first intersecting conductive pattern SL1 may ultimately be electrically connected to each other.

The third insulating layer IL3 may cover at least a portion of the second intersecting conductive pattern SL2 extending on the upper surface of the second semiconductor chip 120. In some embodiments, the third insulating layer IL3 may entirely cover the second intersecting conductive pattern SL2 extending on the upper surface of the second semiconductor chip 120.

The third insulating layer IL3 may be arranged between the first conductive pattern L1, the second conductive pattern L2, and the second intersecting conductive pattern SL2; thus, the first conductive pattern L1 may be spaced apart from the second intersecting conductive pattern SL2 by the third insulating layer IL3, and the second conductive pattern L2 may be spaced apart from the second intersecting conductive pattern SL2 by the third insulating layer IL3. The second intersecting conductive pattern SL2 may be connected to the first chip pad C21 at a portion of the first chip pad C21 having a length that is greater than that of the second chip pad C22. The third insulating layer IL3 may cover the second insulating layer IL2, and thus, the first chip pad C21 may be connected to the first conductive pattern L1 on the remaining portions except for a portion of the first chip pad C21. Because the first conductive pattern L1 and the second intersecting conductive pattern SL2 are connected to the first chip pad C21, the first chip pad C21, the first conductive pattern L1, and the second intersecting conductive pattern SL2 may ultimately be electrically connected to each other.

The fourth insulating layer IL4 may cover at least a portion of the third intersecting conductive pattern SL3 extending on the upper surface of the third semiconductor chip 130. In some embodiments, the fourth insulating layer IL4 may entirely cover the third intersecting conductive pattern SL3 extending on the upper surface of the third semiconductor chip 130.

The fourth insulating layer IL4 may be arranged between the first conductive pattern L1, the second conductive pattern L2, and the third intersecting conductive pattern SL3; thus, the first conductive pattern L1 may be spaced apart from the third intersecting conductive pattern SL3 by the fourth insulating layer IL4, and the second conductive pattern L2 may be spaced apart from the third intersecting conductive pattern SL3 by the fourth insulating layer IL4. The third intersecting conductive pattern SL3 may be connected to the first chip pad C31 at a portion of the first chip pad C31 having a length that is greater than that of the second chip pad C32. The fourth insulating layer IL4 may cover the third intersecting conductive pattern SL3, and thus, the first chip pad C31 may be connected to the first conductive pattern L1 on the remaining portions except for a portion of the first chip pad C31. Because the first conductive pattern L1 and the third intersecting conductive pattern SL3 are connected to the first chip pad C31, the first chip pad C31, the first conductive pattern L1, and the third intersecting conductive pattern SL3 may ultimately be electrically connected to each other.

Because the first intersecting conductive pattern SL1 connects at least some of the plurality of first chip pads C11, the plurality of first chip pads C11, which are connected by the first intersecting conductive pattern SL1, may be electrically connected to each other collectively. This arrangement may also be applied to the second intersecting conductive pattern SL2 to the fourth intersecting conductive pattern SL4.

The first insulating layer IL1 to the fourth insulating layer IL4 may each include polyimide, a polymer, an organic material such as polyimide silicon, an UV curable material, a thermosetting liquid-crystal polymer, a combination thereof, or other similar materials known to one of ordinary skill in the art.

Alternatively, in some embodiments, the first insulating layer IL1 to the fourth insulating layer IL4 may each include a polymer membrane and metal-containing particles dispersed in the polymer membrane. The polymer membrane may vary, and examples of the polymer membrane may include an epoxy mold compound or parylene. The above metal-containing particles may be metal oxide, metal nitride, metal carbide, metal sulfide, or metal coated with an insulating material. Metals included in the metal-containing particles may be, for example, aluminum (Al), magnesium (Mg), iron (Fe), manganese (Mn), copper (Cu), chromium (Cr), cobalt (Co), or nickel (Ni). In some embodiments, the first insulating layer IL1 to the fourth insulating layer IL4 may be formed through silver deposition, distribution, coating, or screen printing.

The first conductive pattern L1 may be wiring related to a power system. Similarly, the first substrate pad S01 and the first side substrate pad S11 to the fourth side substrate pad S14 may each be a pad related to the power system. For example, the first conductive pattern L1, the first substrate pad S01, and the first side substrate pad S11 to the fourth side substrate pad S14 may each be configured to transmit at least one of a power voltage VCCQ, a ground voltage VSSQ, and External Voltage Control (EVC).

The second conductive pattern L2 may be wiring configured to disconnect a signal including data. The second substrate pad S02 may be a pad configured to transmit a signal including data. For example, the second conductive pattern L2 and the second substrate pad S02 may each be configured to transmit data signals DQ and data strobe signals DQS configured to transmit the timings at which the data signals DQ for transmitting data, addresses, or commands are latched.

In the semiconductor package 1 according to embodiments, side substrate pads are provided on the lateral portions of the semiconductor chip stack, and some of the chip pads of the semiconductor chip stacks may be connected by the side substrate pads and the intersecting conductive patterns. Thus, the overall inductance of a power system including wiring and pads is reduced, and a voltage noise level of the power system including the wiring and the pads decreases so that the quality of the power system of the semiconductor package 1 may be improved.

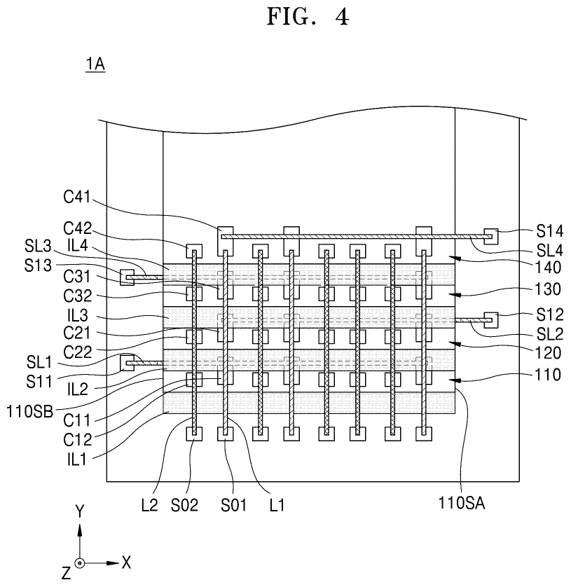

FIG. 4 is a plan view of a semiconductor package 1A according to embodiments. Any details that are not described below may be substantially the same as those provided above.

Referring to FIG. 4, on the upper surface of the package substrate 200, a first substrate pad S01, a second substrate pad S02, a first side substrate pad S11, a second side substrate pad S12, a third side substrate pad S13, and a fourth side substrate pad S14 may be provided. The first side substrate pad S11, the second side substrate pad S12, the third side substrate pad S13, and the fourth side substrate pad S14 may be alternately arranged with respect to the first semiconductor chip 110. For example, the first side substrate pad S11 may be provided in the direction of the first side surface 110SA of the first semiconductor chip 110, the second side substrate pad S12 may be provided in the direction of the second side surface 110SB of the first semiconductor chip 110, the third side substrate pad S13 may be provided in the direction of the first side surface 110SA of the first semiconductor chip 110, and the fourth side substrate pad S14 may be provided in the direction of the second side surface 110SB of the first semiconductor chip 110.

The first intersecting conductive pattern SL1 to the fourth intersecting conductive pattern SL4 may be connected to the first side substrate pad S11 to the fourth side substrate pad S14, respectively. The first intersecting conductive pattern SL1 may extend on the upper surface of the first semiconductor chip 110 and be bent in a vertical direction, thus extending to the first side surface 110SA of the first semiconductor chip 110. The second intersecting conductive pattern SL2 may extend on the upper surface of the second semiconductor chip 120, the side surface of the second semiconductor chip 120, the second side surface 110SB of the first semiconductor chip 110, and the upper surface of the package substrate 200.

The third intersecting conductive pattern SL3 may extend on the upper surface of the third semiconductor chip 130, the side surface of the third semiconductor chip 130, the side surface of the second semiconductor chip 120, the first side surface 110SA of the first semiconductor chip 110, and the upper surface of the package substrate 200. The fourth intersecting conductive pattern SL4 may extend on the upper surface of the fourth semiconductor chip 140, the side surface of the fourth semiconductor chip 140, the side surface of the third semiconductor chip 130, the side surface of the second semiconductor chip 120, the second side surface 110SB of the first semiconductor chip 110, and the upper surface of the package substrate 200.

In some embodiments, the first side substrate pad S11 to the fourth side substrate pad S14 may be arranged randomly, rather than alternately. For example, the first side substrate pad S11 and the fourth side substrate pad S14 may be provided in the direction of the first side surface 110SA, and the second side substrate pad S12 and the third side substrate pad S13 may be provided in the direction of the second side surface 110B. Alternatively, for example, the first side substrate pad S11 and the second side substrate pad S12 may be provided in the direction of the first side surface 110SA, and the third side substrate pad S13 and the fourth side substrate pad S14 may be provided in the direction of the second side surface 110SB. Alternatively, for example, the first side substrate pad S11, the second side substrate pad S12, and the third side substrate pad S13 may be provided in the direction of the first side surface 110SA, and the fourth side substrate pad S14 may be provided in the direction of the second side surface 110SB.

The overall inductance of a power system including wiring and pads is reduced, and a voltage noise level of the power system including the wiring and the pads decreases in the semiconductor package 1A according to embodiments so that the quality of the power system of the semiconductor package 1A may be improved. In addition, the side substrate pads are alternately arranged in the semiconductor package 1A, and thus, the space where the side substrate pads are arranged may be more flexibly utilized.

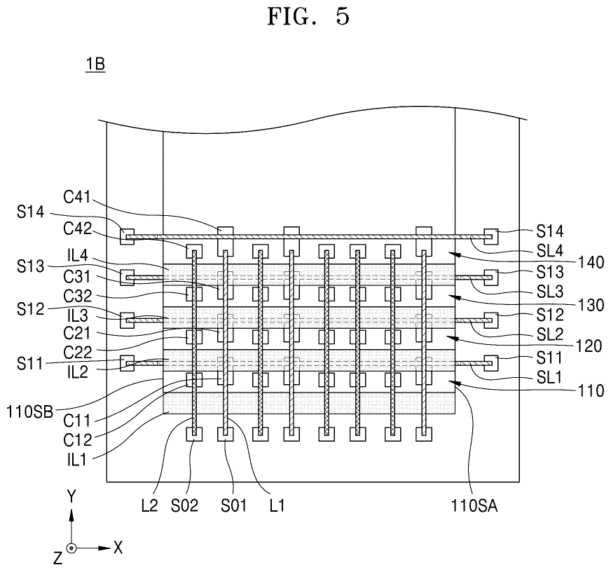

FIG. 5 is a plan view of a semiconductor package 1B according to embodiments. Any details that are not described below may be substantially the same as those provided above.

Referring to FIG. 5, on the upper surface of the package substrate 200, a first substrate pad S01, a second substrate pad S02, a first side substrate pad S11, a second side substrate pad S12, a third side substrate pad S13, and a fourth side substrate pad S14 may be provided. The first side substrate pad S11, the second side substrate pad S12, the third side substrate pad S13, and the fourth side substrate pad S14 may each be provided in the direction of the first side surface 110SA of the first semiconductor chip 110 and the direction of the second side surface 110SB of the first semiconductor chip 110. Therefore, at least two of each of the first side substrate pad S11, the second side substrate pad S12, the third side substrate pad S13, and the fourth side substrate pad S14 may be provided on the package substrate 200.

The first intersecting conductive pattern SL1 to the fourth intersecting conductive pattern SL4 may be connected to the first side substrate pad S11 to the fourth side substrate pad S14, respectively. The first intersecting conductive pattern SL1 may be connected to at least two first side substrate pads S11. The first intersecting conductive pattern SL1 may extend on the upper surface of the first semiconductor chip 110 and be bent in the vertical direction, thus extending to the first side surface 110SA and the second side surface 110SB of the first semiconductor chip 110.

The second intersecting conductive pattern SL2 may be connected to at least two second side substrate pads S12. The second intersecting conductive pattern SL2 may bidirectionally extend on the upper surface of the second semiconductor chip 120 and extend on the opposite side surfaces of the second semiconductor chip 120, thus extending to the first side surface 110SA and the second side surface 110SB of the first semiconductor chip 110. The connection relationships between the third intersecting conductive pattern SL3 and the third side substrate pad S13 and between the fourth intersecting conductive pattern SL4 and the fourth side substrate pad S14 may be understood based on the descriptions regarding those between the first intersecting conductive pattern SL1 and the first side substrate pad S11 and between the second intersecting conductive pattern SL2 and the second side substrate pad S12.

In some embodiments, at least some of the first side substrate pad S11 to the fourth side substrate pad S14 may be provided in plurality. For example, the first side substrate pad S11 to the third side substrate pad S13 may each be arranged both on the first side surface 110SA and the second side surface 110SB of the first semiconductor chip 110, and the fourth side substrate pad S14 may be arranged either on the first side surface 110SA and the second side surface 110SB of the first semiconductor chip 110. Alternatively, the first side substrate pad S11 and the second side substrate pad S12 may each be arranged both on the first side surface 110SA and the second side surface 110SB of the first semiconductor chip 110, and the third side substrate pad S13 and the fourth side substrate pad S14 may each be arranged either on the first side surface 110SA and the second side surface 110SB of the first semiconductor chip 110.

The overall inductance of a power system including wiring and pads may be reduced, and a voltage noise level of the power system including the wiring and the pads may decrease in the semiconductor package 1B according to embodiments. Additionally, because at least two side substrate pads are connected to intersecting conductive patterns, the quality of the power system of the semiconductor package 1B may be improved.

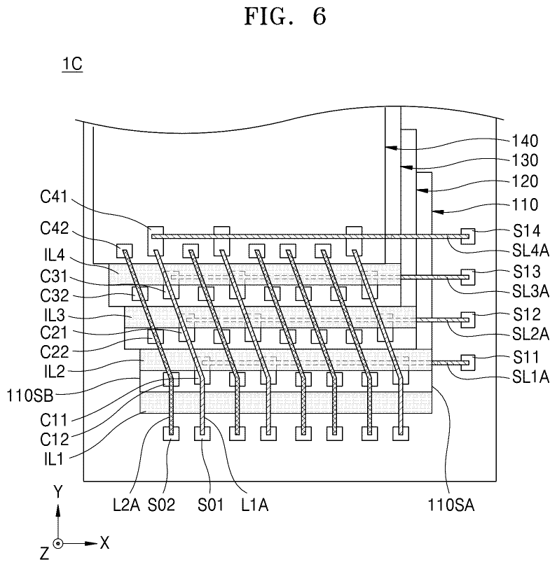

FIG. 6 is a plan view of a semiconductor package 1C according to embodiments. Any details that are not described below may be substantially the same as those provided above.

Referring to FIG. 6, the first semiconductor chip 110 to the fourth semiconductor chip 140 may be offset diagonally and stacked in sequence. The diagonal offset may indicate that the second semiconductor chip 120 is laterally offset on the first semiconductor chip 110 and the offset direction includes both a first-direction component and a second-direction component in a plan view. As the second semiconductor chip 120 is offset on the first semiconductor chip 110 in a diagonal direction, a portion of the upper surface of the first semiconductor chip 110, which is adjacent to the first side surface 110SA of the first semiconductor chip 110, may not be covered by the second semiconductor chip 120. For example, as shown in FIG. 6, the diagonal direction may be a direction that includes a negative first-direction component (the −X-axis direction) and a positive second-direction component (the Y-axis direction). However, the diagonal direction is not limited to the example described above.

The third semiconductor chip 130 may be diagonally offset on the second semiconductor chip 120, and a portion of the upper surface of the second semiconductor chip 120, which is adjacent to the side surface of the second semiconductor chip 120 in the first direction, may not be covered by the third semiconductor chip 130. The fourth semiconductor chip 140 may be diagonally offset on the third semiconductor chip 130, and a portion of the upper surface of the third semiconductor chip 130, which is adjacent to the side surface of the third semiconductor chip 130 in the first direction, may not be covered by the fourth semiconductor chip 140.

A second intersecting conductive pattern SL2A to a fourth intersecting conductive pattern SL4A may extend on the exposed portions of the upper surfaces of the first semiconductor chip 110 to the third semiconductor chip 130. For example, the second intersecting conductive pattern SL2A may extend on the upper surface of the second semiconductor chip 120, the side surface of the second semiconductor chip 120, the upper surface of the first semiconductor chip 110, the first side surface 110SA of the first semiconductor chip 110, and the upper surface of the package substrate 200. The third intersecting conductive pattern SL3A may extend on the upper surface of the third semiconductor chip 130, the side surface of the third semiconductor chip 130, the upper surface of the second semiconductor chip 120, the side surface of the second semiconductor chip 120, the upper surface of the first semiconductor chip 110, the first side surface 110SA of the first semiconductor chip 110, and the upper surface of the package substrate 200.

The fourth intersecting conductive pattern SL4A may extend on the upper surface of the fourth semiconductor chip 140, the side surface of the fourth semiconductor chip 140, the upper surface of the third semiconductor chip 130, the side surface of the third semiconductor chip 130, the upper surface of the second semiconductor chip 120, the side surface of the second semiconductor chip 120, the upper surface of the first semiconductor chip 110, the first side surface 110SA of the first semiconductor chip 110, and the upper surface of the package substrate 200.

A first conductive pattern LIA and a second conductive pattern L2A may each extend along the upper surface of the first insulating layer IL1, the upper surface of the first semiconductor chip 110, the upper surface of the second insulating layer IL2, the upper surface of the second semiconductor chip 120, the upper surface of the third insulating layer IL3, the upper surface of the third semiconductor chip 130, the upper surface of the fourth insulating layer IL4, and the upper surface of the fourth semiconductor chip 140. A portion of the first conductive pattern LIA and a portion of the second conductive pattern L2A may each extend from the upper surface of the first insulating layer IL1 to the upper surface of the package substrate 200.

The first conductive pattern LIA may include a first portion and a second portion, wherein the first portion extends to the first chip pad C11 of the first semiconductor chip 110, the first chip pad C21 of the corresponding second semiconductor chip 120, the first chip pad C31 of the corresponding third semiconductor chip 130, and the first chip pad C41 of the corresponding fourth semiconductor chip 140, and the second portion extends from the first chip pad C11 of the first semiconductor chip 110 to the first substrate pad S01 of the package substrate 200.

Because of the arrangements of the first semiconductor chip 110 to the fourth semiconductor chip 140 that are offset diagonally and stacked in sequence, the first portion of the first conductive pattern LIA may extend in the diagonal direction. In some embodiments, the extension direction of the first portion of the first conductive pattern LIA may be substantially the same as the direction in which the first semiconductor chip 110 to the fourth semiconductor chip 140 are offset.

The extension direction of the second portion of the first conductive pattern LIA may be different from the extension direction of the first portion of the first conductive pattern LIA. For example, as shown in FIG. 6, the second portion of the first conductive pattern LA may extend in the second direction, and the first portion of the first conductive pattern LIA may obliquely extend from the second direction.

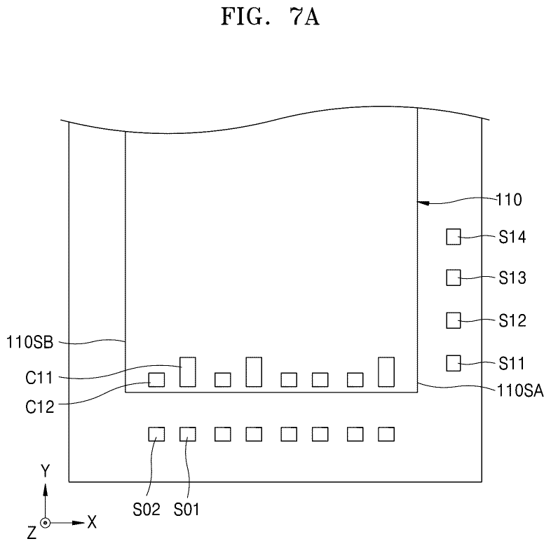

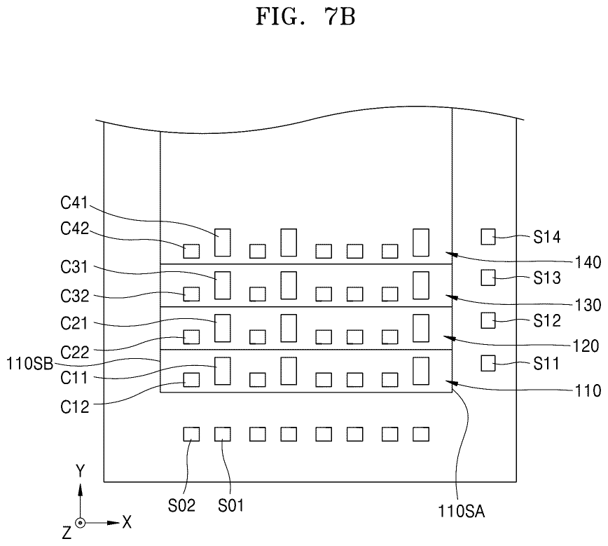

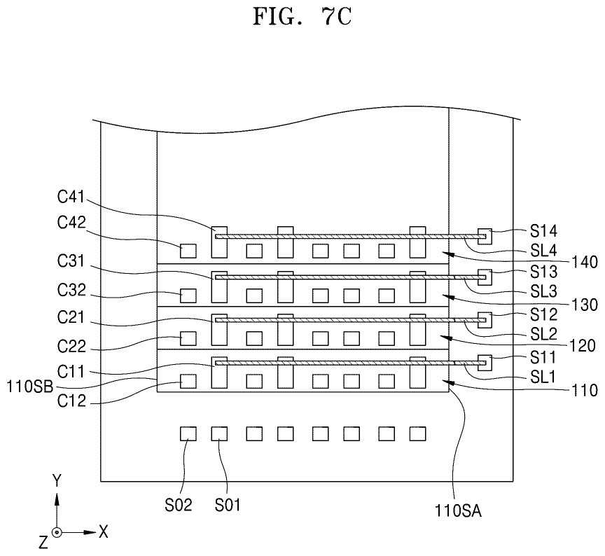

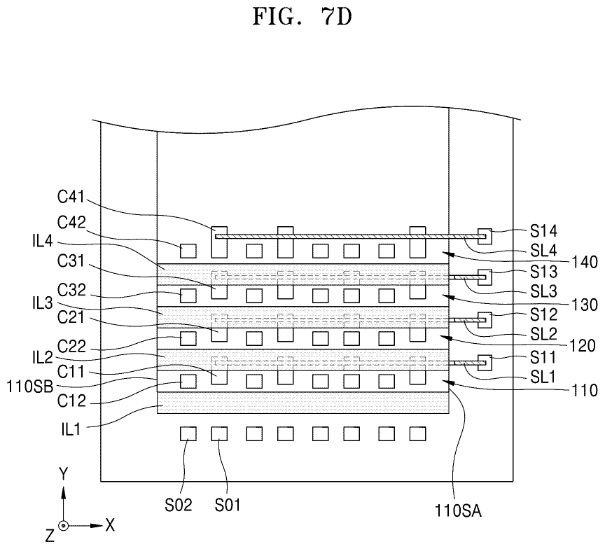

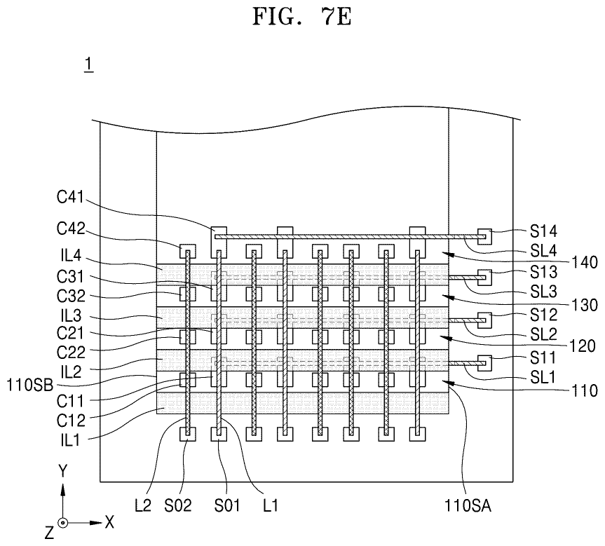

FIGS. 7A to 7E are plan views for explaining a method of manufacturing the semiconductor package 1 in sequence, according to embodiments. Any details that are not described below may be substantially the same as those provided above.

Referring to FIG. 7A, the first semiconductor chip 110 may be arranged on the package substrate 200. The first substrate pad S01, the second substrate pad S02, and the side substrate pads may be provided on the upper surface of the package substrate 200. The side substrate pads may include, for example, the first side substrate pad S11, the second side substrate pad S12, the third side substrate pad S13, and the fourth side substrate pad S14. The first adhesive film may be provided on the lower surface of the first semiconductor chip 110, and the first semiconductor chip 110 may be attached to the upper surface of the package substrate 200 by the first adhesive film.

Referring to FIG. 7B, the second semiconductor chip 120 may be laterally offset on the first semiconductor chip 110, and the third semiconductor chip 130 and the fourth semiconductor chip 140 may be laterally offset and arranged in sequence.

Referring to FIG. 7C, the first intersecting conductive pattern SL1, the second intersecting conductive pattern SL2, the third intersecting conductive pattern SL3, and the fourth intersecting conductive pattern SL4 may be formed. Although not shown in FIG. 7C, before the first intersecting conductive pattern SL1, the second intersecting conductive pattern SL2, the third intersecting conductive pattern SL3, and the fourth intersecting conductive pattern SL4 are formed, seed layers may be formed first at locations where the first intersecting conductive pattern SL1 to the fourth intersecting conductive pattern SL4 are to be formed, and then the first intersecting conductive pattern SL1 to the fourth intersecting conductive pattern SL4 may be formed on the seed layers, wherein the seed layers are the foundation for respective conductive patterns.

Referring to FIG. 7D, a first insulating layer IL1, a second insulating layer IL2, a third insulating layer IL3, and a fourth insulating layer IL4 may be formed on a portion of the upper surface of the package substrate 200, a portion of the upper surface of the first semiconductor chip 110, a portion of the upper surface of the second semiconductor chip 120, and a portion of the upper surface of the third semiconductor chip 130, respectively. The first insulating layer IL1, the second insulating layer IL2, the third insulating layer IL3, and the fourth insulating layer IL4 may be formed using various methods, such as Chemical Vapor Deposition (CVD), spin coating, spray coating, and dipping.

Referring to FIG. 7E, the first conductive pattern L1 and the second conductive pattern L2 may be formed. The seed layers, which are the foundation for forming respective conductive patterns, may be formed first at the locations where the first conductive pattern L1 and the second conductive pattern L2 are to be formed, and then the first conductive pattern L1 and the second conductive pattern L2 may be formed on the seed layers.

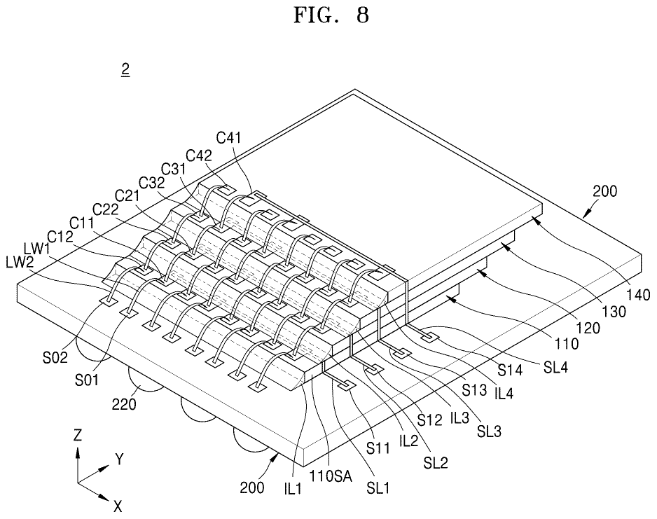

FIG. 8 is a perspective view of a semiconductor package 2 according to embodiments. Any details that are not described below may be substantially the same as those provided above. The differences between the semiconductor package 2 of FIG. 8 and the semiconductor package 1 of FIGS. 1 to 3 are mainly described.

Referring to FIG. 8, the semiconductor package 2 may include a package substrate 200, a first semiconductor chip 110, a second semiconductor chip 120, a third semiconductor chip 130, and a fourth semiconductor chip 140.

A first conductive wire LW1 may be connected to a first chip pad C11 of the first semiconductor chip 110, a first chip pad C21 of the corresponding second semiconductor chip 120, a first chip pad C31 of the corresponding third semiconductor chip 130, and a first chip pad C41 of the corresponding fourth semiconductor chip 140. In addition, the first conductive wire LW1 may be connected to a first substrate pad S01 of the package substrate 200. The first conductive wire LW1 may be formed through a wiring bonding process. Electrical connections between corresponding chip pads on different semiconductor chips may be established through the first conductive wire LW1 and a second conductive wire LW2 described below.

The first conductive wire LW1 may contact the first chip pad C11 of the first semiconductor chip 110 and the first chip pad C21 of the corresponding second semiconductor chip 120 and may be electrically connected thereto. However, the first conductive wire LW1 extending between the first chip pad C11 of the first semiconductor chip 110 and the first chip pad C21 of the corresponding second semiconductor chip 120 may not contact the second insulating layer IL2. This arrangement may also be applied to the first chip pad C31 of the third semiconductor chip 130 and the first chip pad C41 of the fourth semiconductor chip 140.

The first conductive wire LW1 may contact the first substrate pad S01 of the package substrate 200 and the first chip pad C11 of the first semiconductor chip 110 and may be electrically connected thereto. The first conductive wire LW1 extending between the first substrate pad S01 of the package substrate 200 and the first chip pad C11 of the first semiconductor chip 110 may not be in contact with the first insulating layer IL1.

The first insulating layer IL1 may be provided, the first insulating layer IL1 extending on the side surface of the first semiconductor chip 110 and the upper surface of the package substrate 200. The first conductive wire LW1 may be spaced apart from the first insulating layer IL1. The first conductive wire LW1 may be spaced apart from each of the second insulating layer IL2, the third insulating layer IL3, and the fourth insulating layer IL4 that are other insulating layers.

The first chip pad C11 of the first semiconductor chip 110 may have a length that is greater than a length of the second chip pad C12 of the first semiconductor chip 110 in a direction. For example, as shown in FIG. 8, the length of the first chip pad C11 of the first semiconductor chip 110 in the second direction may be greater than that of the second chip pad C12 of the first semiconductor chip 110 in the second direction. In the second direction, the region where the first chip pad C11 of the first semiconductor chip 110 has a greater length than the second chip pad C12 thereof, may be in contact with the first intersecting conductive pattern SL1, and thus, the first chip pad C11 of the first semiconductor chip 110 may be connected to the first intersecting conductive pattern SL1.

Such a connection relationship between the first chip pad C11 of the first semiconductor chip 110 and the first intersecting conductive pattern SL1 may be applied to the connection relationships between the first chip pad C21 of the second semiconductor chip 120 and the second intersecting conductive pattern SL2, between the first chip pad C31 of the third semiconductor chip 130 and the third intersecting conductive pattern SL3, and between the first chip pad C41 of the fourth semiconductor chip 140 and the fourth intersecting conductive pattern SL4. The first intersecting conductive pattern SL1 may connect at least some of the first chip pads C11, and all of the first chip pads C11 connected by the first intersecting conductive pattern SL1 may be electrically connected collectively. This configuration may be similarly applied to the second intersecting conductive pattern SL2 to the fourth intersecting conductive pattern SL4.

The second conductive wire LW2 may be connected to the second chip pad C12 of the first semiconductor chip 110, the second chip pad C22 of the corresponding second semiconductor chip 120, the second chip pad C32 of the corresponding third semiconductor chip 130, and the second chip pad C42 of the corresponding fourth semiconductor chip 140. In addition, the second conductive wire LW2 may be connected to the second substrate pad S02 of the package substrate 200. The second conductive wire LW2 may be formed through a wiring bonding process.

The second conductive wire LW2 may contact the second chip pad C12 of the first semiconductor chip 110 and the second chip pad C22 of the corresponding second semiconductor chip 120 and may be electrically connected thereto. However, the second conductive wire LW2 extending between the second chip pad C12 of the first semiconductor chip 110 and the second chip pad C22 of the corresponding second semiconductor chip 120 may not be in contact with the second insulating layer IL2. This arrangement may be similarly applied to the first chip pad C31 of the third semiconductor chip 130, the first chip pad C41 of the corresponding fourth semiconductor chip 140, and the first substrate pad S01 of the corresponding package substrate 200.

The first conductive wire LW1 may be wiring related to the power system. The first substrate pad S01, the first side substrate pad S11 to the fourth side substrate pad S14, and the first chip pads C11, C21, C31, and C41 that are respectively included in the first semiconductor chip 110 to the fourth semiconductor chip 140 may also be pads that are related to the power system. The second conductive wire LW2 may be wiring configured to disconnect a signal including data. The second chip pads C12, C22, C32, and C42 respectively included in first semiconductor chip 110 to the fourth semiconductor chip 140 and the second substrate pad S02 may be pads configured to transmit signals including data.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments of inventive concepts have been particularly shown and described with reference to embodiments thereof, it will be understood that various changes in form and details may be made therein without departing from the spirit and scope of the following claims.

What is claimed is:

1. A semiconductor package comprising:
a package substrate;
a first semiconductor chip on the package substrate;
a second semiconductor chip on the first semiconductor chip and laterally offset from the first semiconductor chip;
a plurality of chip pads,
the plurality of chip pads including a first chip pad on the first semiconductor chip, a second chip pad on the first semiconductor chip, a first chip pad on the second semiconductor chip, and a second chip pad on the second semiconductor chip, respectively;
a first substrate pad on the package substrate;
a second substrate pad on the package substrate;
a first side substrate pad on the package substrate;
a first conductive pattern that extends on the first chip pad on the first semiconductor chip, the first chip pad on the second semiconductor chip, and the first substrate pad on the package substrate; and
a first intersecting conductive pattern on the first chip pad of the first semiconductor chip, the first intersecting conductive pattern extending on the first semiconductor chip in a first direction, wherein
the first intersecting conductive pattern is spaced apart from the first conductive pattern,
the first substrate pad and the second substrate pad are laterally spaced apart from the first semiconductor chip, and
the first side substrate pad is apart from a first side surface of the first semiconductor chip, and
a first length of the first chip pad on the first semiconductor chip is greater than a second length of the second chip pad on the first semiconductor chip.

2. The semiconductor package of claim 1, further comprising:
a second conductive pattern extending on the second chip pad of the first semiconductor chip, the second chip pad of the second semiconductor chip, and the second substrate pad of the package substrate, wherein
the first intersecting conductive pattern is spaced apart from the second conductive pattern.

3. The semiconductor package of claim 1, wherein
the first substrate pad and the second substrate pad are spaced apart from the first semiconductor chip in a second direction,
the second direction is orthogonal to the first direction, and
the first side substrate pad is spaced apart from the first semiconductor chip in the first direction.

4. The semiconductor package of claim 1, wherein
the first conductive pattern extends in a second direction, and
the second direction is orthogonal to the first direction.

5. The semiconductor package of claim 1, wherein
the first intersecting conductive pattern extends on an upper surface of the first semiconductor chip, the first side surface of the first semiconductor chip, and an upper surface of the package substrate, and
the first intersecting conductive pattern is electrically connected to the first side substrate pad and the first chip pad on the first semiconductor chip.

6. The semiconductor package of claim 1, wherein the first side surface of the first semiconductor chip and a side surface of the second semiconductor chip are arranged in a vertical direction.

7. The semiconductor package of claim 1, further comprising:
a second intersecting conductive pattern on the first chip pad of the second semiconductor chip and extending on the second semiconductor chip in a second direction, the second direction being orthogonal to the first direction; and
a second side substrate pad on the package substrate, wherein
the first side substrate pad is laterally spaced apart from the first side surface of the first semiconductor chip,
the second side substrate pad is laterally spaced apart from a second side surface of the first semiconductor chip, and
the second side surface of the first semiconductor chip is opposite the first side surface of the first semiconductor chip.

8. The semiconductor package of claim 1, wherein
the first side substrate pad is among a plurality of side substrate pads on the package substrate,
some of the plurality of side substrate pads are laterally spaced apart from the first side surface of the first semiconductor chip, and other side substrate pads among the plurality of side substrate pads are laterally spaced apart from a second side surface of the first semiconductor chip,
the first intersecting conductive pattern is electrically connected to two of the plurality of side substrate pads, and
the second side surface of the first semiconductor chip is opposite to the first side surface of the first semiconductor chip.

9. The semiconductor package of claim 1, further comprising:
a first insulating layer extending on the first side surface of the first semiconductor chip and an upper surface of the package substrate,
wherein the first insulating layer is spaced apart from the first substrate pad and the second substrate pad.

10. The semiconductor package of claim 1, further comprising:
a second insulating layer extending on a side surface of the second semiconductor chip and an upper surface of the first semiconductor chip,
wherein the second insulating layer is between the first conductive pattern and the first intersecting conductive pattern.

11. The semiconductor package of claim 10, wherein the second insulating layer covers a portion of the first chip pad on the first semiconductor chip.

12. The semiconductor package of claim 10, wherein the first conductive pattern extends on the second insulating layer.

13. The semiconductor package of claim 10, wherein the second insulating layer covers a portion of the first intersecting conductive pattern on the first semiconductor chip.

14. The semiconductor package of claim 10, wherein the second insulating layer is spaced apart from the second chip pad on the second semiconductor chip.

15. The semiconductor package of claim 1, wherein the first length of the first chip pad is in a range of 1.5 times to 4 times the second length of the second chip pad.

16. The semiconductor package of claim 1, wherein
a first portion of the first conductive pattern connects the first chip pad of the first semiconductor chip to the first chip pad of the second semiconductor chip,
a second portion of the first conductive pattern connects the first chip pad of the first semiconductor chip to the first substrate pad, and
an extension direction of the first portion of the first conductive pattern is different from an extension direction of the second portion of the first conductive pattern.

17. A semiconductor package comprising:
a package substrate comprising a first substrate pad, a second substrate pad, and a first side substrate pad on an upper surface of the package substrate;
a first semiconductor chip on the package substrate;
a second semiconductor chip on the first semiconductor chip and laterally offset from the first semiconductor chip;
a plurality of chip pads,
the plurality of chip pads including a first chip pad on the first semiconductor chip, a second chip pad on the first semiconductor chip, a first chip pad on the second semiconductor chip, and a second chip pad on the second semiconductor chip, respectively;
a first insulating layer extending on a side surface of the first semiconductor chip and the upper surface of the package substrate;
a second insulating layer extending on a side surface of the second semiconductor chip and an upper surface of the first semiconductor chip;
a first conductive pattern electrically connecting the first chip pad of the first semiconductor chip, the first chip pad of the second semiconductor chip, and the first substrate pad;
a second conductive pattern electrically connecting the second chip pad of the first semiconductor chip, the second chip pad of the second semiconductor chip, and the second substrate pad; and
a first intersecting conductive pattern connected to at least a portion of the first chip pad of the first semiconductor chip, wherein
the first intersecting conductive pattern extends on the first semiconductor chip in a first direction,
the second semiconductor chip is offset from the first semiconductor chip in a second direction,
the second direction is orthogonal to the first direction, and
the first conductive pattern and the second conductive pattern each extend in the second direction.

18. The semiconductor package of claim 17, wherein
a portion of the first intersecting conductive pattern extends in a third direction,
the third direction is orthogonal to both the first direction and the second direction, and
the first intersecting conductive pattern extends on the upper surface of the first semiconductor chip, the side surface of the first semiconductor chip, and the upper surface of the package substrate.

19. The semiconductor package of claim 17, wherein
the first conductive pattern, the first substrate pad, the first chip pad of the first semiconductor chip, the first chip pad of the second semiconductor chip, and the first side substrate pad are configured to transmit power signals, and
the second conductive pattern, the second substrate pad, the second chip pad of the first semiconductor chip, and the second chip pad of the second semiconductor chip are configured to transmit data signals.

20. A semiconductor package comprising:
a package substrate comprising a first substrate pad, a second substrate pad, and a first side substrate pad on an upper surface of the package substrate;
a first semiconductor chip on the package substrate;
a second semiconductor chip on the first semiconductor chip and laterally offset from the first semiconductor chip;
a plurality of chip pads,
the plurality of chip pads including a first chip pad on the first semiconductor chip, a second chip pad on the first semiconductor chip, a first chip pad on the second semiconductor chip, and a second chip pad on the second semiconductor chip, respectively;
a first insulating layer extending on a side surface of the first semiconductor chip and an upper surface of the package substrate;
a second insulating layer extending on a side surface of the second semiconductor chip and an upper surface of the first semiconductor chip;
a first conductive pattern electrically connecting the first chip pad of the first semiconductor chip, the first chip pad of the second semiconductor chip, and the first substrate pad;
a second conductive pattern electrically connecting the second chip pad of the first semiconductor chip, the second chip pad of the second semiconductor chip, and the second substrate pad; and
a first intersecting conductive pattern connected to at least a portion of the first chip pad of the first semiconductor chip, wherein
the first intersecting conductive pattern extends on the first semiconductor chip in a first direction,
the second semiconductor chip is offset from the first semiconductor chip in a second direction,
the second direction is orthogonal to the first direction,
the first conductive pattern and the second conductive pattern extend in the second direction,
the first intersecting conductive pattern is spaced apart from the second conductive pattern,
the first side substrate pad is apart of a first side surface of the first semiconductor chip, and
the first substrate pad and the second substrate pad are spaced apart from the first semiconductor chip in the second direction,
a first length of the first chip pad on the first semiconductor chip is greater than a second length of the second chip pad on the first semiconductor chip,
the first length is in a range of 1.5 times to 4 times the second length,
the first intersecting conductive pattern extends on an upper surface of the first semiconductor chip, the first side surface of the first semiconductor chip, and an upper surface of the package substrate,
the first intersecting conductive pattern is electrically connected to the first side substrate pad and the first chip pad of the first semiconductor chip,
the first side surface of the first semiconductor chip and the side surface of the second semiconductor chip are arranged in a vertical direction,
the first insulating layer is spaced apart from the first substrate pad and the second substrate pad,
the second insulating layer is between the first conductive pattern and the first intersecting conductive pattern, covers a portion of the first chip pad on the first semiconductor chip, and covers at least a portion of the first intersecting conductive pattern on the first semiconductor chip,
the first conductive pattern and the second conductive pattern extend on the second insulating layer,
a part of the first intersecting conductive pattern extends on the side surface of the first semiconductor chip in a third direction,
the third direction is orthogonal to both the first direction and the second direction,
the first conductive pattern, the first substrate pad, the first chip pad of the first semiconductor chip, the first chip pad of the second semiconductor chip, and the first side substrate pad are configured to transmit power signals, and
the second conductive pattern, the second substrate pad, the second chip pad of the first semiconductor chip, and the second chip pad of the second semiconductor chip are configured to transmit data signals.
